(19) United States
(12) Patent Application Publication
(10) Pub. No.: US 2013/0234103 A1
(43) Pub. Date: Sep. 12, 2013

(54) NANOSCALE SWITCHING DEVICE WITH AN AMORPHOUS SWITCHING MATERIAL

(71) Applicant: HEWLETT-PACKARD DEVELOPMENT COMPANY, L.P., Houston, TX (US)

(72) Inventors: Jianhua Yang, Pa;p Alto, CA (US); R. Stanley Williams, Portola Valley, CA (US); Gilberto Medeiros Ribeiro, Palo Alto, CA (US)

(73) Assignee: Hewlett-Packard Development Company, L.P., Houston, TX (US)

(21) Appl. No.: 13/867,335

(22) Filed: Apr. 22, 2013

Related U.S. Application Data
(63) Continuation-in-part of application No. 13/259,180, filed on Sep. 23, 2011.

(30) Foreign Application Priority Data
Aug. 31, 2009 (US) PCT/US2009/055538

(51) Int. Cl. H01L 45/00

(52) U.S. Cl. CPC H01L 45/1253; H01L 45/16
USPC 257/5; 257/2; 438/104

(57) ABSTRACT

Nanoscale switching devices are disclosed. The devices have a first electrode of a nanoscale width; a second electrode of a nanoscale width; and a layer of an active region disposed between and in electrical contact with the first and second electrodes. The active region contains a switching material capable of carrying a significant amount of defects which can trap and de-trap electrons under electrical bias. The switching material is in an amorphous state. A nanoscale crossbar array containing a plurality of the devices and a method for making the devices are also disclosed.

### CROSS-REFERENCE TO RELATED APPLICATION

The present application is a continuation-in-part of application Ser. No. 13/259,180, filed Sep. 23, 2011.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of contract No. HR0011-09-3-0001 awarded by DARPA.

### BACKGROUND

The continuous trend in the development of electronic devices has been to minimize the sizes of the devices. While the current generation of commercial microelectronics are based on sub-micron design rules, significant research and development efforts are directed towards exploring devices on the nanoscale, with the dimensions of the devices often measured in nanometers or tens of nanometers. Besides the significant reduction of individual device size and much higher packing density compared to microscale devices, nanoscale devices may also provide new functionalities due to physical phenomena on the nanoscale that are not observed on the microscale.

For instance, resistive switching in nanoscale devices using titanium oxide as the switching material has recently been reported. The resistive switching behavior of such a device has been linked to the memristor circuit element theory originally predicted in 1971 by L. O. Chua. The discovery of the memristive behavior in the nanoscale switch has generated significant interests, and there are substantial on-going research efforts to further develop such nanoscale switches and to implement them in various applications.

There are, however, some critical challenges in improving the performance of the devices in order to bring them from the laboratory to actual applications. Generally, there are many operational characteristics an ideal resistive switching device should possess in order to meet the demands of different applications. They include: very low current level (e.g., <5 μA) needed to switch the device into ON and OFF states, no need for an electroforming process to “break-in” the device, great endurance of operation cycling, small device variance, state stability for non-volatile operation, capability of controllable multiple state setting, fast switching speed, large ON/OFF resistance ratio, and large absolute resistance value in the ON state (e.g., >1 Mohm) etc. Significant research efforts have been put into producing nanoscale resistance switching devices that have most, if not all, of these desired characteristics.

### BRIEF DESCRIPTION OF THE DRAWINGS

Some examples of the invention are described, by way of example, with respect to the following figures:

FIG. 1 is a cross-sectional view of a nanoscale switching device in accordance with an example of the invention;

FIG. 2 is a schematic cross-sectional view of an example of a nanoscale switching device having an amorphous switching material;

FIG. 3 is a flow diagram showing a method of an example of the invention for forming a nanoscale switching device with an amorphous switching material;

FIG. 4 is a plot of I-V curves of an experimental sample of a resistive switching device having an amorphous switching material; and

FIG. 5 is a schematic cross-sectional view of a crossbar array of nanoscale switching devices with an amorphous switching material in accordance with an example of the invention.

### DETAILED DESCRIPTION

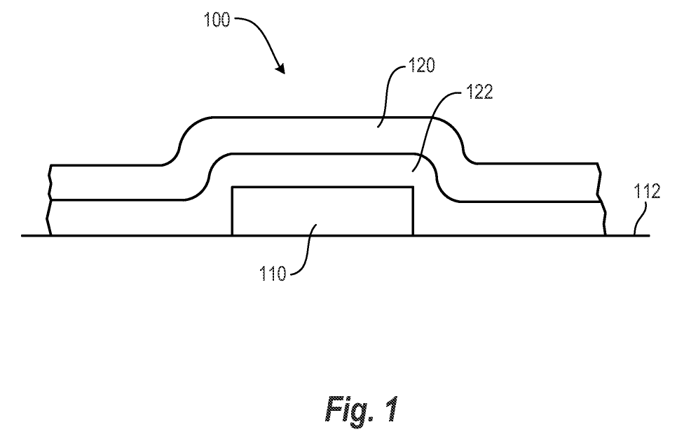

FIG. 1 shows an example of a nanoscale switching device 100 in accordance with the invention that has many desired characteristics. The switching device 100 includes a bottom electrode 110 and a top electrode 120, and an active region 122 disposed between the two electrodes. Each of the bottom and top electrodes 110 and 120 is formed of a conductive material and has a width and a thickness on the nanoscale. As used hereinafter, the term “nanoscale” means the object has one or more dimensions smaller than one micrometer. In this regard, each of the electrodes may be in the form of a nanowire. Generally, the active region 122 contains a single layer of switching material that is capable of carrying a significant amount of defects, which can trap and de-trap electrons under electrical bias, which is responsible for switching behavior of the device, as will be described in greater detail below.

By a significant number of defects is meant a defect density on the order of 3×10¹⁹/cm³. However, this value can vary by a few orders of magnitude, depending on the specific materials employed. In comparison, a typical defect density in solids is on the order of 10¹⁵ to 10¹⁶/cm³.

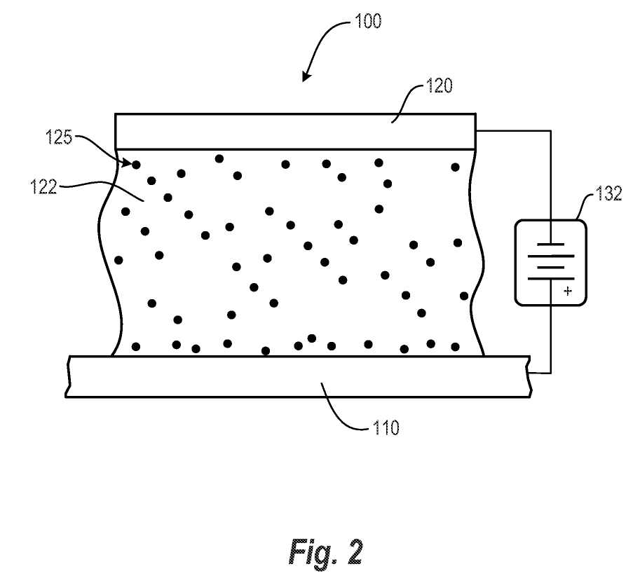

FIG. 2 shows, in schematic form, the switching device 100. As shown in FIG. 2, the active region 122 of the switching device 100 includes a switching material that is in an amorphous state and is formed by means of deposition at room-temperature or a lower temperature. The thickness of the switching layer in some examples may be in the range of 3 nm to 100 nm, and in other examples about 30 nm or less.

Generally, the switching material may be electronically semiconducting or nominally insulating. Many different materials with their respective suitable defects can be used as the switching material. Materials that exhibit suitable properties for switching include oxides, sulfides, selenides, nitrides, carbides, phosphides, arsenides, chlorides, and bromides of transition and rare earth metals. Suitable switching materials also include elemental semiconductors such as Si and Ge, and compound semiconductors such as III-V and II-VI compound semiconductors. The III-V semiconductors include, for instance, BN, BP, BSb, AlP, AlSb, GaAs, GaP, GaN, InN, InP, InAs, and InSb, and ternary and quaternary compounds. The II-VI compound semiconductors include, for instance, CdSe, CdS, CdTe, ZnSe, ZnS, ZnO, and ternary compounds. These listings of possible switching materials are not exhaustive and do not restrict the scope of the present invention.

In some examples, oxides, such as TiO₂, Ta₂O₅, HfO₂, Al₂O₃ SiO₂, or GeO₂, may be used. In other examples, nitrides, such as TaNₓ (1<x<2), AlN, Si₃N₄, or Ge₃N₄, may be used.

Defects 125 act as traps for electrons and are shown in FIG. 2 as distributed throughout the single layer that is the active region 122. The defects in the materials may be dangling bonds or other point defects associated with dopants. It appears that fabricating the single layer in an amorphous state, particularly where the temperature during the fabricating process is at room temperature or below, enhances the number of defects 125.

The dopant species depends on the particular type of switching material chosen, and may be cations, anions or vacancies, or impurities as electron donors or acceptors. For instance, in the case of transition metal oxides such as TiO₂, the dopant species may be oxygen vacancies. For GaN, the dopant species may be nitride vacancies. For compound semiconductors, the dopants may be n-type or p-type impurities. Different from the ionic motion-based memristors, the voltage and current levels applied here are generally not high enough to cause drift of dopants, but high enough to induce electron trapping and de-trapping.

By way of example, as shown in FIG. 2, in one example the switching material may be TiO₂. In this case, the dopants may be oxygen vacancies (V_{O}²⁺), which may trap and de-trap electrons under electrical bias. The nanoscale switching device 100 can be switched between ON and OFF states by controlling the concentration and distribution of the trapped electrons in the switching material in the active region 122. When a DC switching voltage from a voltage source 132 is applied across the top and bottom electrodes 110 and 120, an electric field is created across the active region 122. This electric field, if of a sufficient strength and proper polarity, may drive the electrons to be trapped in the switching material, thereby turning the device into an OFF state.

If the polarity of the electric field is reversed, the trapped electrons may be extracted from the switching material, thereby turning the device into an ON state. In this way, the switching is reversible and may be repeated. Due to the relatively large electric field needed to cause electron trapping and de-trapping, after the switching voltage is removed, the resistance of the device remains stable in the switching material. The system will behave as a memristor.

The state of the switching device 100 may be read by applying a read voltage to the bottom and top electrodes 110 and 120 to sense the resistance across these two electrodes. The read voltage is typically much lower than the threshold voltage required to switch the device, so that the read operation does not alter the ON/OFF state of the switching device.

The switching behavior described above may be based on different mechanisms. In one mechanism, the switching behavior may be an “interface” phenomenon. Initially, with a high trapped electron level in the switching material, the interface of the switching material and the top electrode 120 may have a high electronic barrier that is difficult for electrons to tunnel through. As a result, the device has a relatively high resistance. When a switching voltage to turn the device ON is applied, the trapped electrons are extracted. The decreased concentration of trapped electrons in the electrode interface region changes its electrical property from one with high electronic barrier to one with lower electronic barrier, with a significantly reduced electronic barrier height or width. As a result, electrons can tunnel through the interface much more easily, and this may account for the significantly reduced overall resistance of the switching device.

In another mechanism, the reduction of resistance may be a “bulk” property of the switching material in the switching layer. The reduction of the trapped electrons in the switching material causes the resistance across the switching material to fall, and this may account for the decrease of the overall resistance of the device between the top and bottom electrodes. It is also possible that the resistance change is the result of a combination of both the bulk and interface mechanisms. Even though there may be different electron-trapping mechanisms for explaining the switching behavior, it should be noted that the present invention does not rely on or depend on any particular mechanism for validation, and the scope of the invention is not restricted by which switching electron-trapping mechanism is actually at work.

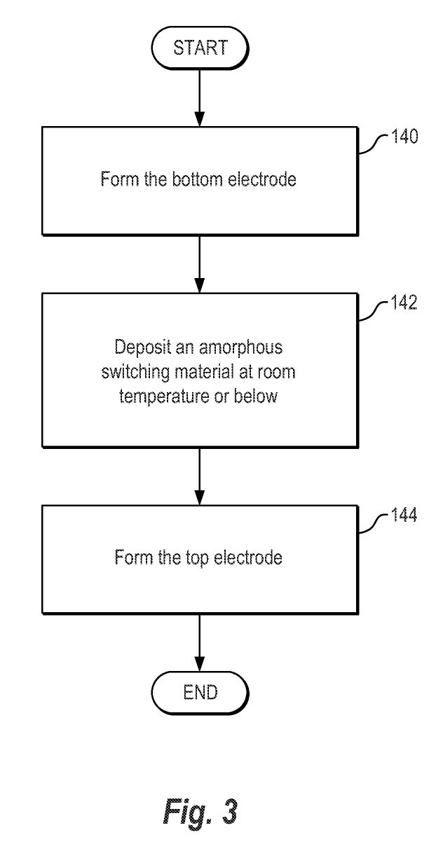

In accordance with an example of the invention, many of the desirable characteristics of an ideal nanoscale switching device are achieved by employing an amorphous switching material deposited at or below room temperature. FIG. 3 shows a method of forming such a device. To form the device, the bottom electrode is formed on a substrate (block 140). The switching material in an amorphous state is then deposited onto the substrate over the bottom electrode (block 142). In one example, the material is deposited by means of physical vapor deposition. In this process, a target of a suitable material is sputtered with ions, such that the target material is removed from the target and deposited onto the substrate surface. The deposition may be performed in the environment of a selected reactive gas such that the gas reacts with the target material coming off the target to form a compound that is the intended material to be deposited onto the substrate. By way of example, in one example the switching material to be deposited is amorphous TiO₂. In that case, the target material may be Ti, and the deposition is performed in an environment of a mixture of Ar gas and O₂ gas. The oxygen reacts with the Ti sputtered off the target and forms TiO₂ on the surface of the substrate. In should be noted that the TiO₂ formed this way may not be stoichiometric and may have a small oxygen deficiency that provides oxygen vacancies as dopants. Different from a conventional memristor, where an active layer plus a dopant reservoir layer are used for dopants to move between these two layers, the current device function does not invoke dopant motion and has only one layer of amorphous materials.

In accordance with an aspect of one example of the invention, the substrate is at kept at room temperature during the deposition, i.e., no external heating is applied to the substrate during the deposition. In other examples, the substrate may be cooled during the deposition to a temperature below the room temperature, to further enhance the amorphous growth of the switching material. After the amorphous switching material deposited onto the substrate and over the bottom electrode reaches a desired thickness, the deposition is stopped. The top electrode is then formed on top of the switching material layer (block 144).

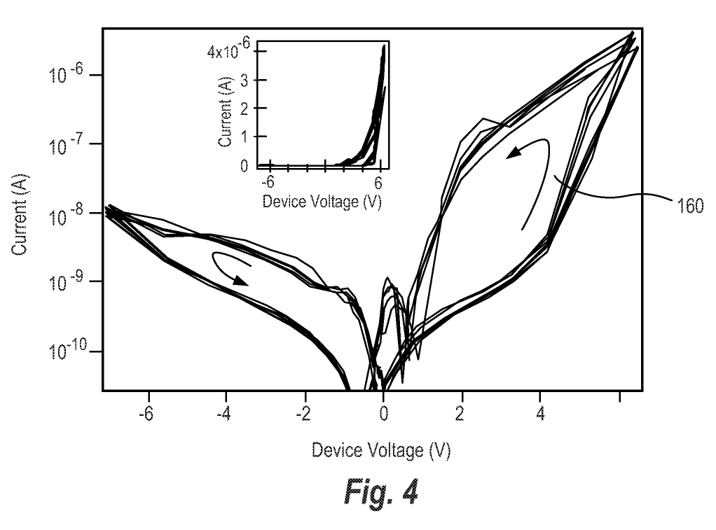

This invention is based on the discovery, as an unexpected result, that the amorphous switching material deposited at room temperature or a lower temperature may exhibit many of the desired characteristics of a nanoscale resistive switching device. An important one of such characteristics is a very low current level (e.g., <5 μA) required to switch the device into ON and OFF states. In addition, the absolute resistance values for both ON and OFF states are higher than 1 Mohms at the reading voltage, which is usually close to the half of the switching voltage. In some examples, the absolute values for both ON and OFF states are higher than 20 Mohms. For illustration of this characteristic, FIG. 4 shows a plot of I-V curves 160 of an experimental sample of a switching device that has room-temperature-deposited amorphous TiO₂ as its switching material. The thickness of the amorphous TiO₂ layer in this sample is 75 nm. For experimental purposes, the sample was made to have a relatively large junction size of 5×5 μm². It can be seen that the I-V curves of this sample exhibit the hysteresis behavior of a resistive memristic switching device. Moreover, the current required to switch the device to the ON state is about 4×10⁻⁶ amp (4 μA), which is very low, and the current for switching the device to the OFF state is even lower. If the current requirement is scaled down for a switching device with a nanoscale junction, it is expected that the switching current will be further reduced, possibly by a few orders of magnitude.

Besides having a low switching current level, the sample further exhibits the desirable property of not requiring an electroforming process. Prior switching devices using a metal oxide switching material typically require an initial irreversible electroforming step to put the devices in a state capable of normal switching operations. The electroforming process is typically done by applying a voltage sweep to a relatively high voltage, such as from 0V up to −20V for negative forming or 0V to +10V for positive forming. The sweep range is set such that device is electroformed before reaching the maximum sweep voltage by exhibiting a sudden jump to a higher current and lower voltage in the I-V curve. The electroforming operation is difficult to control due to the suddenness of the conductivity change. Moreover, the electroformed devices exhibit a wide variance of operational properties depending on the details of the electroforming. Electroforming in the traditional memristor is used to create mobile dopants, such as oxygen vacancies, in oxide switching materials. However, the switching of the device in the current application does not invoke mobile dopants and therefore does not need electroforming. It has been discovered that the switching device with RT-deposited amorphous TiO₂ as the switching material does not require such an electroforming step. In this regard, the device as fabricated has an initial resistance that is between the OFF resistance and ON resistance, and is able to produce the I-V curve of normal switching during the first sweep. Removing the need for electroforming not only simplifies the operation procedure but allows for smaller device variance.

Another important property exhibited by the sample is great endurance, which means that the switching behavior of the device remains substantially unchanged after many switching cycles. This property is likely linked to the low switching current required and the avoidance of electroforming. The sample also shows good long-term stability, with only very small relaxation observed in I-V sweep curves with the device in the ON and OFF states. Also, the device exhibits a high ON/OFF resistance ratio of about 1000, which enables accurate setting and detection of the ON/OFF states of the device.

In addition, the sample shows that it can be controllably set into multiple states, instead of just the ON and OFF states. Starting in the OFF state, the device can be set into intermediate states by applying voltage sweeps or pulses with the maximum sweep voltage below the switching voltage needed for directly switching the device to the ON state. With each such voltage sweep or pulse, the I-V curve is moved closer to that of the ON state. Similarly, with the device starting in the ON state, successive voltage sweeps or pulses of the opposite polarity move the I-V curve incrementally closer to the I-V curve of the OFF state. Thus, by controlling the magnitude and duration of the voltage sweeps, the device can be placed into a selected intermediate state from either direction.

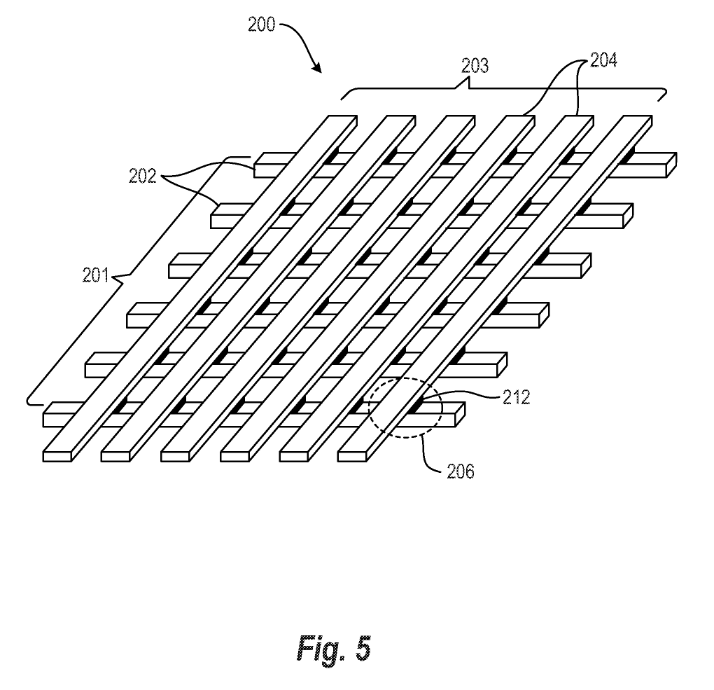

The nanoscale switching device with an amorphous switching material deposited at or below room temperature may be formed into an array for various applications. FIG. 5 shows an example of a two-dimensional array 200 of such switching devices. The array 200 has a first group 201 of generally parallel nanowires 202 running in a first direction, and a second group 203 of generally parallel nanowires 204 running in a second direction at an angle, such as 90 degrees, from the first direction. The two layers of nanowires 202 and 204 form a two-dimensional lattice which is commonly referred to as a crossbar structure, with each nanowire 202 in the first layer intersecting a plurality of the nanowires 204 of the second layer. A switching device 206 may be formed at each intersection of the nanowires 202 and 204. The switching device 206 has a nanowire of the second group 203 as its top electrode and a nanowire of the first group 201 as the bottom electrode, and an active region 212 containing a switching material between the two nanowires. In accordance with an example of the invention, the switching material in the active region 212 is amorphous and is formed by deposition at or below room temperature.

In the foregoing description, numerous details are set forth to provide an understanding of the present invention. However, it will be understood by those skilled in the art that the present invention may be practiced without these details. While the invention has been disclosed with respect to a limited number of examples, those skilled in the art will appreciate numerous modifications and variations therefrom. It is intended that the appended claims cover such modifications and variations as fall within the true spirit and scope of the invention.

What is claimed is:

1. A nanoscale switching device, comprising:
a first electrode of a nanoscale width;
a second electrode of a nanoscale width; and
a layer of active region disposed between and in electrical contact with the first and second electrodes, the active region containing a switching material capable of carrying a significant amount of defects which can trap and de-trap electrons under electrical bias, the switching material being in an amorphous state.

2. A nanoscale switching device as in claim 1, wherein the switching material in the active region has a thickness in a range of 3 nm to 100 nm.

3. A nanoscale switching material as in claim 1, wherein the switching material is selected from the group consisting of (a) oxides, sulfides, selenides, nitrides, carbides, phosphides, arsenides, chlorides, and bromides of transition and rare earth metals; (b) Si and Ge; and III-V or II-VI compound semiconductors.

4. A nanoscale switching device as in claim 3, wherein the switching material is an oxide or a nitride.

5. A nanoscale switching device as in claim 4, wherein the switching material is selected from the group consisting of titanium oxide, tantalum oxide, hafnium oxide, aluminum oxide, silicon oxide, germanium oxide, tantalum nitride, aluminum nitride, silicon nitride, and germanium nitride.

6. A nanoscale switching device as in claim 1, wherein the amorphous state of the switching material is formed at room temperature or below.

7. A nanoscale crossbar array comprising:
a first group of conductive nanowires running in a first direction;
a second group of conductive nanowires running in a second direction and intersecting the first group of nanowires; and
a plurality of switching devices formed at intersections of the first and second groups of nanowires, each switching device having a first electrode formed by a first nanowire of the first group and a second electrode formed by a second nanowire of the second group, and an active region disposed at the intersection between and in electrical contact with the first and second nanowires, the active region containing a switching material capable of carrying a significant amount of defects which can trap and de-trap electrons under electric field, the switching material being in an amorphous state.

8. A nanoscale crossbar array as in claim 7, wherein the switching layer has a thickness in a range of 3 nm to 100 nm.

9. A nanoscale crossbar array as in claim 7, wherein the switching material is selected from the group consisting of (a) oxides, sulfides, selenides, nitrides, carbides, phosphides, arsenides, chlorides, and bromides of transition and rare earth metals; (b) Si and Ge; and III-V or II-VI compound semiconductors.

10. A nanoscale crossbar array as in claim 9, wherein the switching material is an oxide or a nitride.

11. A nanoscale crossbar array as in claim 10, wherein the switching material is selected from the group consisting of titanium oxide, tantalum oxide, hafnium oxide, aluminum oxide, silicon oxide, germanium oxide, tantalum nitride, aluminum nitride, silicon nitride, and germanium nitride.

12. A nanoscale crossbar array as in claim 7, wherein the amorphous state of the switching material is formed at room temperature or below.

13. A method of forming a nanoscale switching device, comprising:
forming a first electrode on a substrate;
depositing at or below room temperature a switching material in an amorphous state over the first electrode, the switching material being capable of carrying a species of dopants and transporting the dopants under an applied electric field; and
forming a second electrode on top of the amorphous switching material.

14. A method as in claim 13, wherein the switching material has a thickness in a range of 3 nm and 100 nm.

15. A method as in claim 13, wherein the switching material is selected from the group consisting of (a) oxides, sulfides, selenides, nitrides, carbides, phosphides, arsenides, chlorides, and bromides of transition and rare earth metals; (b) Si and Ge; and III-V or II-VI compound semiconductors.

16. A method as in claim 15, wherein the switching material is an oxide or a nitride.

17. A nanoscale crossbar array as in claim 16, wherein the switching material is selected from the group consisting of titanium oxide, tantalum oxide, hafnium oxide, aluminum oxide, silicon oxide, germanium oxide, tantalum nitride, aluminum nitride, silicon nitride, and germanium nitride.
